(19) United States
(12) Patent Application Publication
(10) Pub. No.: US 2016/0305817 A1
(43) Pub. Date: Oct. 20, 2016

(54) PROXIMITY LUMINANCE SENSOR AND METHOD FOR MANUFACTURING SAME

(71) Applicant: ITM SEMICONDUCTOR CO., LTD, Chungcheongbuk-do (KR)

(72) Inventors: Yung Jun KIM, Gyeonggi-do (KR); Ja Guen GU, Chungcheongbuk-do (KR); Su Seok LEE, Chungcheongbuk-do (KR)

(21) Appl. No.: 14/781,086

(22) PCT Filed: Mar. 5, 2014
(86) PCT No.: PCT/KR2014/001800

§ 371 Date: Sep. 29, 2015

(30) Foreign Application Priority Data
May 8, 2013 (KR) 10-2013-0052095

(51) Int. Cl. G01J 1/08; H01L 25/16; H01L 33/54; H01L 33/48; H01L 31/0232; H01L 31/16; H01L 33/62; H01L 31/02; G01J 1/44; H01L 33/58

(52) U.S. Cl. CPC G01J 1/08; G01J 1/44; H01L 25/167; H01L 33/54; H01L 33/58; H01L 31/02327; H01L 25/165; H01L 31/16; H01L 33/62; H01L 31/02002; H01L 33/483; H01L 2933/0058; H01L 2933/005

(57) ABSTRACT

The present invention relates to a proximity luminance sensor obtained by assembling a housing array to a printed circuit board array using an adhesive layer, prior to separation into individual proximity luminance sensors, thereby preventing contamination or damage to lenses, decreasing the optical interference phenomenon, reducing the manufacturing cost and manufacturing time, and thus substantially improving productivity. The proximity luminance sensor may comprise: a printed circuit board; a light-emitting chip mounted on the printed circuit board; a light-receiving chip mounted on the printed circuit board; a light-emitting lens unit surrounding the light-emitting chip; a light-receiving lens unit surrounding the light-receiving chip; a housing shaped to surround the light-emitting chip and the light-receiving chip and provided with a light-emitting window, which corresponds to the light-emitting lens unit, and a light-receiving window, which corresponds to the light-receiving lens unit; and an adhesive layer installed between the housing and the printed circuit board.

### TECHNICAL FIELD

The present invention is related to a proximity luminance sensor and a method for manufacturing the same. In particular, the present invention relates to a proximity luminance sensor and a method for manufacturing the same, obtained by assembling a housing array to a printed circuit board array using an adhesive layer, prior to separation into individual proximity luminance sensors, thereby preventing contamination or damage to lenses, decreasing the optical interference phenomenon, reducing the manufacturing cost and manufacturing time, and thus substantially improving productivity.

### BACKGROUND ART

A proximity luminance sensor is widely used for various motion sensing sensors or the like. The proximity luminance sensor can sense a reflected light generated from a light emitting unit such as an infrared emitting device and reflected from a subject, thereby sensing proximity of the subject or illumination of surroundings.

There are two conventional methods of manufacturing proximity luminance sensors.

In the first conventional method of manufacturing a proximity luminance sensor, a light-emitting lens unit and a light-receiving lens unit, both made of transparent material, are molded first on a light-emitting chip and a light-receiving chip in a printed circuit board array, respectively, and then a blocking wall made of opaque material is molded later so as to prevent crosstalk phenomenon in which a light generated from the light-emitting chip is directly transmitted to light-receiving chip.

However, in the first conventional method of manufacturing a proximity luminance sensor, the light-emitting lens unit and the light-receiving lens unit may be contaminated by the opaque material during the molding of the blocking wall.

In the second conventional method of manufacturing a proximity luminance sensor, a light-emitting lens unit and a light-receiving lens unit, both made of transparent material, are molded together on a light-emitting chip and a light-receiving chip in a printed circuit board array, respectively, and then the light-emitting lens unit and the light-receiving lens unit are separated by a sawing process so as to prevent crosstalk phenomenon in which a light generated from the light-emitting chip is directly transmitted to light-receiving chip. Later, the printed circuit board array is separated to form individual devices and then a housing pre-manufactured and made of metal is assembled to each of the individual devices.

However, in the second conventional method of manufacturing a proximity luminance sensor, each of the individually separated printed circuit boards and each of the housings made of metal are manually assembled each other, thereby increasing the manufacturing cost of the housings, and thus substantially decreasing productivity.

### DETAILED DESCRIPTION OF THE INVENTION

### Technical Problem

There are two conventional methods of manufacturing proximity luminance sensors.

In the first conventional method of manufacturing a proximity luminance sensor, a light-emitting lens unit and a light-receiving lens unit, both made of transparent material, are molded first on a light-emitting chip and a light-receiving chip in a printed circuit board array, respectively, and then a blocking wall made of opaque material is molded later so as to prevent crosstalk phenomenon in which a light generated from the light-emitting chip is directly transmitted to light-receiving chip.

However, in the first conventional method of manufacturing a proximity luminance sensor, the light-emitting lens unit and the light-receiving lens unit may be contaminated by the opaque material during the molding of the blocking wall.

In the second conventional method of manufacturing a proximity luminance sensor, a light-emitting lens unit and a light-receiving lens unit, both made of transparent material, are molded together on a light-emitting chip and a light-receiving chip in a printed circuit board array, respectively, and then the light-emitting lens unit and the light-receiving lens unit are separated by a sawing process so as to prevent crosstalk phenomenon in which a light generated from the light-emitting chip is directly transmitted to light-receiving chip. Later, the printed circuit board array is separated to form individual devices and then a housing pre-manufactured and made of metal is assembled to each of the individual devices.

However, in the second conventional method of manufacturing a proximity luminance sensor, each of the individually separated printed circuit boards and each of the housings made of metal are manually assembled each other, thereby increasing the manufacturing cost of the housings, and thus substantially decreasing productivity.

The present invention has an objective to solve the above mentioned problems, and provides a proximity luminance sensor and a method of manufacturing the same. The proximity luminance sensor is obtained by assembling a housing array to a printed circuit board array using an adhesive layer, prior to separation into individual proximity luminance sensors, thereby preventing contamination or damage to lenses, decreasing the optical interference phenomenon, reducing the manufacturing cost and manufacturing time, and thus substantially improving productivity. However, this objective is exemplarily, and thus the scope of the present invention is not limited thereto.

### Technical Solution

According to an aspect of the present invention, a method of manufacturing a proximity luminance sensor includes: mounting a plurality of light-emitting chips and a plurality of light-receiving chips on a printed circuit board array, and connecting a signal transmitting member to each of the chips; molding a light-emitting lens unit surrounding the light-emitting chips and a light-receiving lens unit surrounding the light-receiving lens unit on the printed circuit board array; assembling a housing array having a light-emitting window corresponding to the light-emitting lens unit and a light-receiving window corresponding to the light-receiving lens unit to the printed circuit board array where the light-emitting lens unit and the light-receiving lens unit are molded; and separating individual proximity luminance sensors from the printed circuit board array assembled with the housing array.

In addition, according to some embodiment of the present invention, in the molding of the lens unit, the light-emitting lens unit may include a plurality of light-emitting lens body unit and a light-emitting lens gate and runner unit connecting the light-emitting lens body units. The light-receiving lens unit may includes a plurality of light-receiving body unit and a light-receiving lens gate and runner unit connecting the light-receiving lens body units.

In addition, according to some embodiment of the present invention, the assembling of the housing array may include assembling the printed circuit board array and the housing array using an adhesive layer disposed between the printed circuit board array and the housing array.

In addition, according to some embodiment of the present invention, the separating of the individual proximity luminance sensors may include cutting the housing array along a cutting line using a sawing process

According to an aspect of the present invention, a proximity luminance sensor includes: a printed circuit board; a light-emitting chip mounted on the printed circuit board; a light-receiving chip mounted on the printed circuit board; a light-emitting lens unit surrounding the light-emitting chip; a light-receiving lens unit surrounding the light-receiving chip; a housing shaped to surround the light-emitting chip and the light-receiving chip and provided with a light-emitting window, which corresponds to the light-emitting lens unit, and a light-receiving window, which corresponds to the light-receiving lens unit; and an adhesive layer installed between the housing and the printed circuit board.

In addition, according to some embodiment of the present invention, the housing may include a blocking wall blocking between the light-emitting chip and the light-receiving chip.

In addition, according to some embodiment of the present invention, the housing may include a synthetic resin. Cutting surfaces may be formed on sides of the housing. A portion of light-emitting lens gate and runner unit formed during the molding of the light-emitting lens unit may be exposed on the cutting surface. A portion of light-receiving lens gate and runner unit formed during molding the light-receiving lens unit may be exposed on the cutting surface

### Advantageous Effects

The proximity luminance sensor and the method of manufacturing the same according to the present invention is obtained by assembling a housing array to a printed circuit board array followed by the separation into individual proximity luminance sensors, and thus provides advantageous effects of preventing contamination or damage to lenses, decreasing the optical interference phenomenon, reducing the manufacturing cost and manufacturing time, and thus substantially improving productivity. In addition, the scope of the present invention is not limited to these effects.

### DESCRIPTION OF THE DRAWINGS

FIG. 1 is a perspective diagram of a proximity luminance sensor, according to some embodiments of the present invention.

FIG. 2 is a perspective diagram showing a step of mounting chips and connecting a signal transmitting member in a method of manufacturing a proximity luminance sensor, according to some embodiments of the present invention.

FIG. 3 is a perspective diagram showing a step of molding lens units in the method of manufacturing a proximity luminance sensor of FIG. 2, according to some embodiments of the present invention.

FIG. 4 and FIG. 5 are perspective diagram showing a step of assembling a housing array in the method of manufacturing a proximity luminance sensor of FIG. 2, according to some embodiments of the present invention.

FIG. 6 is a perspective diagram showing a step of separating individual proximity luminance sensors in the method of manufacturing a proximity luminance sensor of FIG. 2, according to some embodiments of the present invention.

FIG. 7 is a perspective diagram showing another example of the housing array in the method of manufacturing a proximity luminance sensor of FIG. 4, according to some embodiments of the present invention.

FIG. 8 is a cross-sectional diagram of FIG. 2, according to some embodiments of the present invention.

FIG. 9 is a cross-sectional diagram of FIG. 3, according to some embodiments of the present invention.

FIG. 10 and FIG. 11 are cross-sectional diagrams of FIG. 4 and FIG. 5, respectively, according to some embodiments of the present invention.

FIG. 12 is a cross-sectional diagram of FIG. 1, according to some embodiments of the present invention.

FIG. 13 is a flowchart of a method of manufacturing the proximity luminance sensor, according to embodiments of the present invention.

### BEST MODE

Reference will now be made in detail to exemplary embodiments, examples of which are illustrated in the accompanying drawings.

However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing.

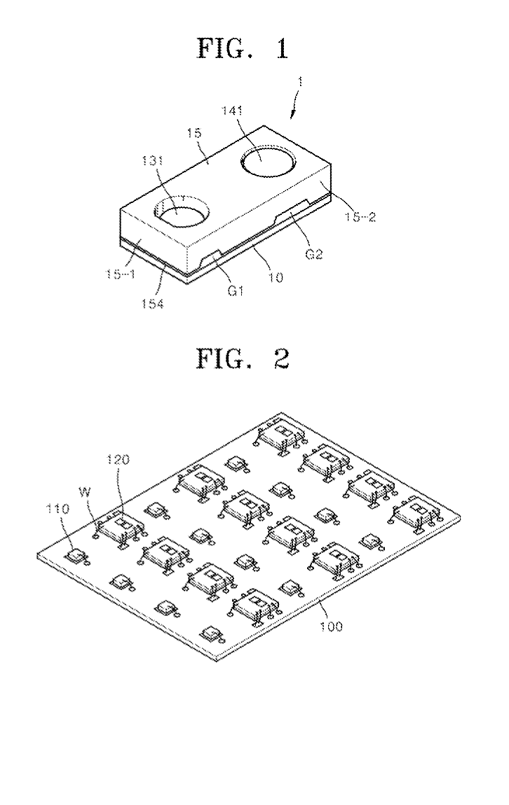

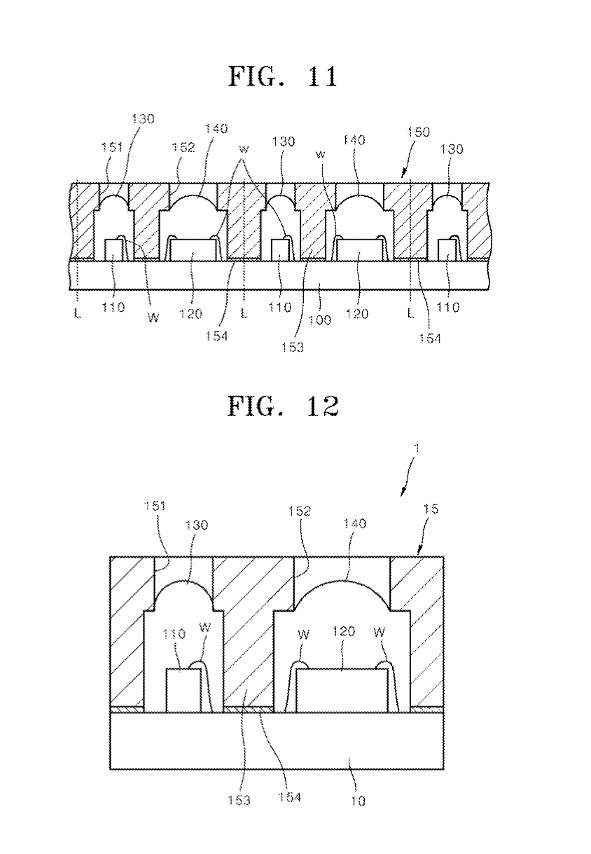

FIG. 1 is a perspective diagram of a proximity luminance sensor, according to some embodiments of the present invention. FIG. 12 is a cross-sectional diagram of FIG. 1, according to some embodiments of the present invention.

As shown in FIG. 1 and FIG. 12, a proximity luminance sensor 1, according to some embodiments of the present invention, includes a printed circuit board 10, a light-emitting chip 110, a light-receiving chip 120, a light-emitting lens unit 130, a light-receiving lens unit 140, a housing 15, and an adhesive layer 154.

That is, the printed circuit board 10 is a substrate supporting the light-emitting chip 110, the light-receiving chip 120, the light-emitting lens unit 130, the light-receiving lens unit 140, the housing 15, and the adhesive layer 154. In the printed circuit board 10, various circuit layers and terminals are installed so as to apply power to the light-emitting chip 110 and receive a sensing signal from the light-receiving chip 120.

Herein, the light-emitting chip 110 is mounted on a first portion of an upper surface of the printed circuit board 10. The light-emitting chip 110 may be a light-emitting device such as a LED illuminating on a subject. The light-emitting chip 110 may be a infrared LED so as to sense proximity of the subject or illumination of surroundings.

As shown in FIG. 1 and FIG. 12, the light-receiving chip 120 is installed on a second portion of an upper surface of the printed circuit board 10. The light-receiving chip 120 may be a light-receiving device receiving a light reflected from the subject.

In addition, the light-emitting lens unit 130 and light-receiving lens unit 140 are mounted on upper portions of the light-emitting chip 110 and the light-receiving chip 120 so as to surround the light-emitting chip 110 and the light-receiving chip 120, respectively. The light-emitting lens unit 130 and light-receiving lens unit 140 are made of a transparent material or a translucent material such as silicone, epoxy, acrylic, glass, sapphire, or the like. In addition, the light-emitting lens unit 130 and light-receiving lens unit 140 are made of various transparent materials or various translucent materials such as transparent molding materials, transparent electrode materials, transparent insulting materials, or the like.

In addition, the housing 15 is an opaque resin material. The housing 15 surrounds the light-emitting chip 110 and light-receiving chip 120 together. The housing 15 includes a light-emitting window 151 corresponding to the light-emitting lens unit 130 and a light-receiving window 152 corresponding to the light-receiving lens unit 140.

Herein, the housing 15 may include a blocking wall 153 blocking between the light-emitting chip 110 and the light-receiving chip 120 so as to prevent a interference phenomenon in which in which a light generated from the light-emitting chip 110 is directly transmitted to light-receiving chip 120, that is, to prevent a crosstalk phenomenon.

The housing 15 may includes a resin such as a thermosetting resin, a thermoplastic resin, or the like. For example, the housing 15 includes a resin, for example, an epoxy resin composite, a silicone resin composite, a modified epoxy resin composite such as a silicone modified epoxy resin, a modified silicone resin composite such as an epoxy modified silicone resin, a polyimide resin composite, a modified polyimide resin composite, a polyphthalamide (PPA), a polycarbonate resin, a polyphenylene sulfide (PPS), a liquid crystal polymer (LCP), an ABS resin, a phenol resin, an acrylic resin, a PBT resin, or the like. In addition, the resin may include a light reflecting material such as a titanium oxide, a silicon dioxide, a titanium dioxide, a zirconium dioxide, potassium titania, alumina, aluminum nitride, boron nitride, mullite, or the like.

In addition, as shown in FIG. 1, the housing 15 includes a synthetic resin. Cutting surfaces 15-1, 15-2 are formed on sides thereof using a sawing process. A portion of light-emitting lens gate and runner unit G1 formed during the molding of the light-emitting lens unit 130 is exposed on the cutting surface 15-2. A portion of light-receiving lens gate and runner unit G2 formed during the molding of the light-receiving lens unit 140 is exposed on the cutting surface 15-2.

The exposure of the portion of light-emitting lens gate and runner unit G1 and the exposure of the portion of light-receiving lens gate and runner unit G2 formed during molding the light-receiving lens unit 140 are caused by the separating of the individual proximity luminance sensors followed by assembling the housing array 15 to the printed circuit board array 100.

The adhesive layer 154 is installed between the housing 15 and the printed circuit board 10 so as to securely fix the housing 15 onto the printed circuit board 10 by the adhesive force.

Herein, the adhesive layer 154 may be made of an opaque material so as to prevent a crosstalk phenomenon in which a light generated from the light-emitting chip 110 is directly transmitted to the light-receiving chip 120

In addition, the adhesive layer 154 may include a thermoplastic resin having polysulfone, polyethersulfone, bisphenol, and/or phenol, biphenyl. The adhesive layer 154 may include various hardener or various resins.

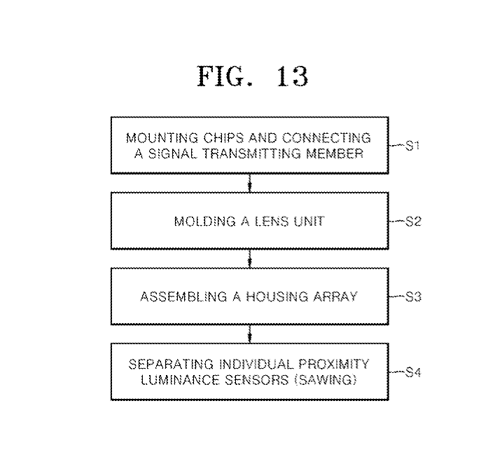

FIG. 13 is a flowchart of a method of manufacturing the proximity luminance sensor, according to embodiments of the present invention.

As shown in FIG. 13, the method of manufacturing the proximity luminance sensor 1, according to embodiments of the present invention, includes a step S1 of mounting chips and connecting a signal transmitting member, a step S2 of molding a lens unit, a step S3 of assembling a housing array, and a step S4 of separating individual proximity luminance sensors.

FIG. 2 is a perspective diagram showing a step S1 of mounting chips and connecting a signal transmitting member in a method of manufacturing a proximity luminance sensor, according to some embodiments of the present invention. FIG. 8 is a cross-sectional diagram of FIG. 2, according to some embodiments of the present invention.

As shown in FIG. 2 and FIG. 8, the step S1 of mounting the chips and connecting the signal transmitting member includes mounting a plurality of light-emitting chips 110 and a plurality of light-receiving chips 120 on a printed circuit board array 100, and connecting a signal transmitting member W to each of the chips;

In the step S1 of mounting the chips and connecting the signal transmitting member, the signal transmitting member W may be wire. In addition, the signal transmitting member W may be configured of various signal transmitting component such as a lead frame, a solder ball, a bump, a circuit layer, flexible circuit layer.

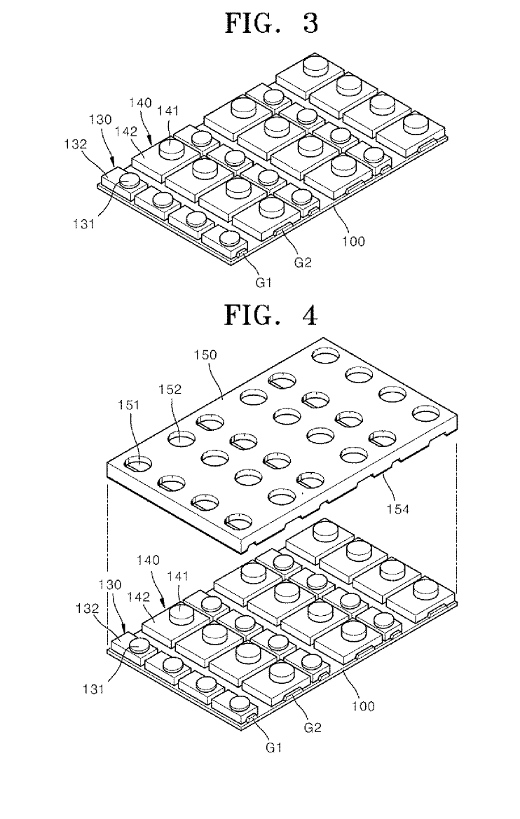

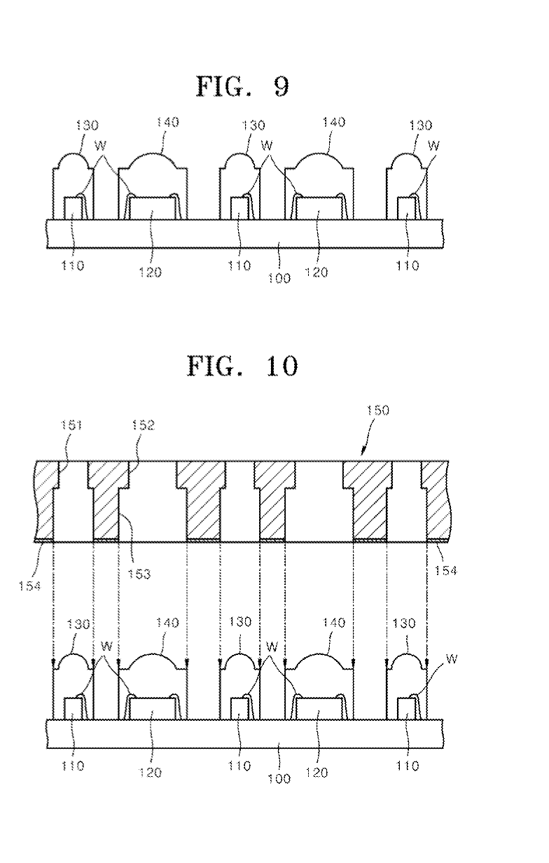

FIG. 3 is a perspective diagram showing a step S2 of molding lens units in the method of manufacturing a proximity luminance sensor of FIG. 2, according to some embodiments of the present invention. FIG. 9 is a cross-sectional diagram of FIG. 3, according to some embodiments of the present invention.

As shown in FIG. 3 and FIG. 9, the step S2 of molding the lens unit includes molding a light-emitting lens unit 130 surrounding the light-emitting chips 110 and a light-receiving lens unit 140 surrounding the light-receiving lens unit 120 on the printed circuit board array 100.

In the step S2 of molding a lens unit, the light-emitting lens unit 130 includes a plurality of light-emitting lens body units 132, in each of which a light-emitting lens 131 exposed by a light-emitting window 151 is formed, and a light-emitting lens gate and runner unit G1 connecting the light-emitting lens body units 132.

In addition, the light-receiving lens unit 140 includes a plurality of light-receiving lens body units 142, in each of which a light-receiving lens 141 exposed a light-receiving window 152 is formed, and a light-receiving lens gate and runner unit G2 connecting the light-receiving lens body units 142.

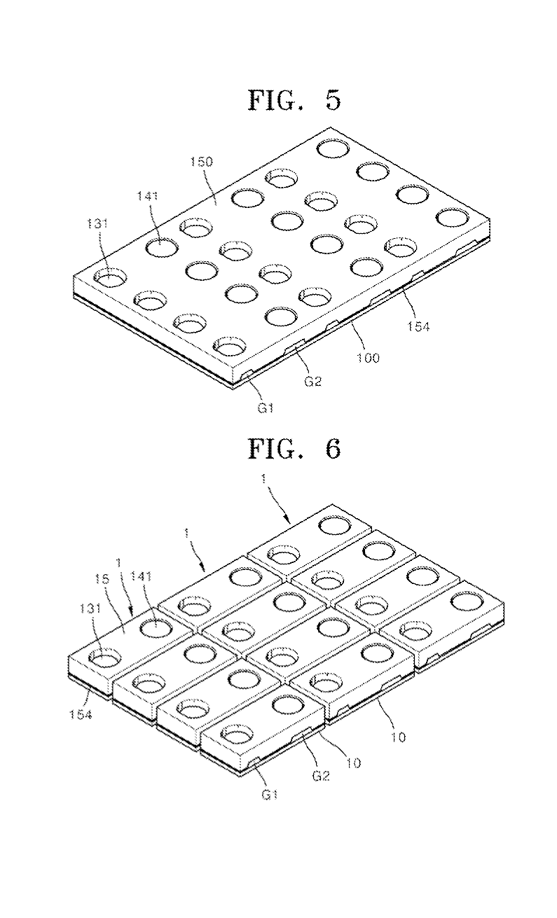

FIG. 4 and FIG. 5 are perspective diagram showing the step S3 of assembling a housing array in the method of manufacturing a proximity luminance sensor of FIG. 2, according to some embodiments of the present invention. FIG. 10 and FIG. 11 are cross-sectional diagrams of FIG. 4 and FIG. 5, respectively, according to some embodiments of the present invention.

As shown in FIG. 4, FIG. 5, FIG. 10 and FIG. 11, the step S3 of assembling the housing array having assembling a housing array 150 having a light-emitting window 151 corresponding to the light-emitting lens unit 130 and a light-receiving window 152 corresponding to the light-receiving lens unit 140 to the printed circuit board array 100 where the light-emitting lens unit 130 and the light-receiving lens unit 140 are molded.

In the step S3 of assembling the housing array, the housing array 150 is assembled to the printed circuit board array 100 using an adhesive layer 154 disposed between the printed circuit board array 100 and the housing array 150.

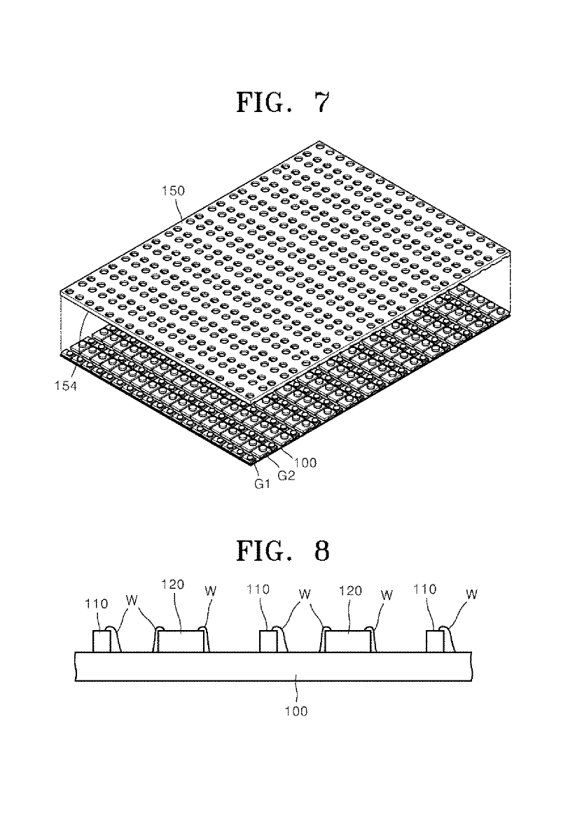

FIG. 7 is a perspective diagram showing another example of the housing array 150 in the method of manufacturing a proximity luminance sensor of FIG. 4, according to some embodiments of the present invention.

As shown in FIG. 7, the housing array 150 includes a plurality of individual housings incorporated each other with rows and columns. The numbers of the rows and columns may be optimized according to manufacturing conditions, manufacturing equipments, molds, and materials.

FIG. 6 is a perspective diagram showing the step S4 of the separating of the individual proximity luminance sensors in the method of manufacturing a proximity luminance sensor of FIG. 2, according to some embodiments of the present invention.

The step S4 of the separating of the individual proximity luminance sensors includes separating individual proximity luminance sensors from the printed circuit board array 100 assembled with the housing array 150.

In the step S4 of the separating of the individual proximity luminance sensors, the housing array 150 may be cut along a cutting line L using a sawing process.

Accordingly, the proximity luminance sensor 1 as shown in FIG. 1 and FIG. 12 may be manufactured by the method of manufacturing the proximity luminance sensor, according to some embodiments of the present invention.

The foregoing is illustrative of exemplary embodiments and is not to be construed as limiting thereof. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

### DESCRIPTION OF REFERENCE NUMBERS

1: proximity luminance sensor

10: printed circuit board

110: light-emitting chip

120: light-receiving chip

130: light-emitting lens unit

140: light-receiving lens unit

15: housing

151: light-emitting window

152: light-receiving window

153: blocking wall

154: adhesive layer

15-1, 15-2: cutting surface

G1: light-emitting lens gate and runner unit

G2: light-receiving gate and runner unit

100: printed circuit board array

W: signal transmitting member

S1: step of mounting chips and connecting a signal transmitting member

S2: step of molding a lens unit

S3: step of assembling a housing array

S4: step of separating individual proximity luminance sensors

L: cutting line

1. A method of manufacturing a proximity luminance sensor, the method comprising:
mounting a plurality of light-emitting chips and a plurality of light-receiving chips on a printed circuit board array, and connecting a signal transmitting member to each of the chips;
molding a light-emitting lens unit surrounding the light-emitting chips and a light-receiving lens unit surrounding the light-receiving lens unit on the printed circuit board array;
assembling a housing array having a light-emitting window corresponding to the light-emitting lens unit and a light-receiving window corresponding to the light-receiving lens unit to the printed circuit board array where the light-emitting lens unit and the light-receiving lens unit are molded; and
separating individual proximity luminance sensors from the printed circuit board array assembled with the housing array.

2. The method of claim 1, wherein, in the molding of the lens unit, the light-emitting lens unit comprises a plurality of light-emitting lens body unit and a light-emitting lens gate and runner unit connecting the light-emitting lens body units,
wherein the light-receiving lens unit comprises a plurality of light-receiving body unit and a light-receiving lens gate and runner unit connecting the light-receiving lens body units.

3. The method of claim 1, wherein, the assembling of the housing array comprises assembling the printed circuit board array and the housing array using an adhesive layer disposed between the printed circuit board array and the housing array.

4. The method of claim 1, wherein the separating of the individual proximity luminance sensors comprises cutting the housing array along a cutting line using a sawing process.

5. A proximity luminance sensor, comprising:
a printed circuit board;
a light-emitting chip mounted on the printed circuit board;
a light-receiving chip mounted on the printed circuit board;
a light-emitting lens unit surrounding the light-emitting chip;
a light-receiving lens unit surrounding the light-receiving chip;
a housing shaped to surround the light-emitting chip and the light-receiving chip and provided with a light-emitting window, which corresponds to the light-emitting lens unit, and a light-receiving window, which corresponds to the light-receiving lens unit; and
an adhesive layer installed between the housing and the printed circuit board.

6. The proximity luminance sensor of claim 5, wherein the housing comprises a blocking wall blocking between the light-emitting chip and the light-receiving chip.

7. The proximity luminance sensor of claim 5, wherein the housing comprises a synthetic resin,
wherein cutting surfaces are formed on sides of the housing,
wherein a portion of light-emitting lens gate and runner unit formed during the molding of the light-emitting lens unit is exposed on the cutting surface,
wherein a portion of light-receiving lens gate and runner unit G2 formed during molding the light-receiving lens unit is exposed on the cutting surface.

8. The proximity luminance sensor of claim 5, wherein the adhesive layer is made of an opaque material including an epoxy composite so as to prevent a crosstalk phenomenon in which a light generated from the light-emitting chip is directly transmitted to the light-receiving chip.
